(19) United States
(12) Patent Application Publication
(10) Pub. No.: US 2025/0158265 A1
(43) Pub. Date: May 15, 2025

(54) Balanced Squid Tunable Coupler

(71) Applicant: NORTHROP GRUMMAN SYSTEMS CORPORATION, FALLS CHURCH, VA (US)

(72) Inventor: Joshua A. STRONG, Ellicott City, MD (US)

(21) Appl. No.: 18/510,347

(22) Filed: Nov. 15, 2023

(51) Int. Cl. H01P 5/18

(52) U.S. Cl. CPC H01P 5/184

(57) ABSTRACT

A tunable coupler system includes an input line configured to receive an input current and a signal line configured to provide a signal line current. The tunable coupler system further includes a first superconducting quantum interference device (SQUID) inductively coupled to the input line and the signal line, and a second SQUID inductively coupled to the input line and the signal line. In addition, the tunable coupler system includes a control line inductively coupled to the first SQUID and the second SQUID. The first SQUID and the second SQUID are configured to couple the input current in the input line to the signal line to form the signal line current. A coupling strength between the input line and the signal line is determined based on a control current in the control line.

### GOVERNMENT INTEREST

The invention was made under Government Contract. Therefore, the US Government has rights to the invention as specified in that contract.

### TECHNICAL FIELD

This disclosure relates generally to superconducting systems, and more specifically to a balanced superconducting quantum interference device (SQUID) tunable coupler.

### BACKGROUND

A superconducting quantum interference device (SQUID) is a very sensitive device used to measure extremely weak magnetic fields. A SQUID include superconducting loop(s) with one or more Josephson Junctions (JJ). There are two main types of SQUIDS: a direct current (DC) SQUID and a radio frequency (RF) SQUID. The DC SQUID includes a superconducting loop with two Josephson Junctions and the RF SQUID has a superconducting loop with a single Josephson Junction. Due to the high sensitivity of SQUIDS, they are employed in a variety of applications as magnetic field sensors, tunable couplers and other superconducting devices.

### SUMMARY

One example includes a tunable coupler system. The tunable coupler system includes an input line configured to receive an input current and a signal line configured to provide a signal line current. The tunable coupler system further includes a first superconducting quantum interference device (SQUID) inductively coupled to the input line and the signal line, and a second SQUID inductively coupled to the input line and the signal line. In addition, the tunable coupler system includes a control line inductively coupled to the first SQUID and the second SQUID. The first SQUID and the second SQUID are configured to couple the input current in the input line to the signal line to form the signal line current, wherein a coupling strength between the input line and the signal line is determined based on a control current in the control line.

Another example includes an integrated circuit (IC). The IC includes an input line included in a first layer of the IC and a signal line included in a second layer of the IC. The IC further includes a first superconducting quantum interference device (SQUID) and a second SQUID included in a third layer of the IC such that the first SQUID and the second SQUID are inductively coupled to the input line and the signal line. In addition, the IC includes a control line included in a fourth layer of the IC such that the control line is inductively coupled to the first SQUID and the second SQUID. The first SQUID and the second SQUID are configured to couple an input current in the input line to the signal line based on a control current in the control line.

### BRIEF DESCRIPTION OF THE DRAWINGS

FIG. 1 illustrates an example of a tunable coupler system.

FIG. 2 illustrates an example tunable coupler system having a first control line input current and a second control line input current in the control line.

FIG. 3 illustrates an example tunable coupler system having a first input line control current and a second input line control current in the input line.

FIG. 4 illustrates an example implementation of a tunable coupler system that includes fixed DC biasing.

FIG. 5 illustrates an example layout of an integrated circuit (IC) that includes a tunable coupler system showing grounded loops.

FIG. 6 illustrates an example layout of an integrated circuit (IC) that includes a tunable coupler system showing SQUID arrangement.

FIG. 7 illustrates an example cross-section of an integrated circuit (IC) that includes a tunable coupler system.

FIG. 8 illustrates a graphical representation of a signal line current, an input current and a control current associated with a tunable coupler system without including a coupling element (e.g., grounded loops).

FIG. 9 illustrates a graphical representation of a signal line current, an input current and a control current associated with a tunable coupler system that includes a coupling element (e.g., grounded loops).

### DETAILED DESCRIPTION

This disclosure relates generally to superconducting systems, and more specifically to a balanced SQUID tunable coupler. In tunable couplers, a SQUID can be utilized to couple an input current from an input line to a signal line. In particular, in tunable couplers, the SQUID is inductively coupled to the input line and to the signal line. The SQUID mediates the coupling between the input line and the signal line according to the equation below:

$${M}_{IN - SIG} = \frac{{M}_{IN - SQUID} {M}_{SIG - SQUID}}{{L}_{SQUID}} \qquad ( 1 )$$

Where M_{IN-SIG} is the mutual inductance between the input line and the signal line, M_{IN-SQUID} is the mutual inductance between the input line and the SQUID, M_{SIG-SQUID} is the mutual inductance between the signal line and the SQUID, and L_{SQUID} is the inductance of the SQUID. In some examples, L_{SQUID} includes a combined inductance of the superconducting loop and the one or more Josephson Junctions (JJs) associated with the SQUID.

The tunable coupler further includes a control line that is coupled to the SQUID. In some examples, a control current that is passed through the control line controls the coupling (e.g., coupling strength) between the input line and the signal line. In particular, the control current that is passed through the control line modulates the mutual inductance, M_{IN-SQUID}, between the input line and the SQUID, and the mutual inductance, M_{SIG-SQUID}, between the signal line and the SQUID, thereby modifying the mutual inductance, M_{IN-SIG}, between the input line and the signal line according to equation (1). In some examples, however, the control current in the control line creates circulating currents in the SQUID which then couples to the input line and the signal line. Such coupled control current in the input line and the signal line is undesirable as the couple control current creates cross-talk in the input line and the signal line.

In order to overcome the above disadvantages, a balanced SQUID tunable coupler is disclosed herein. The balanced SQUID tunable coupler includes two SQUIDS, in particular, a first SQUID and a second SQUID that are inductively coupled to an input line and a signal line. The balanced SQUID tunable coupler further includes a control line (e.g., a single control line) that is coupled to the first SQUID and the second SQUID. The first SQUID and the second SQUID are configured to couple an input current in the input line to the signal line to form a signal line current based on a control current in the control line. Further, the first SQUID and the second SQUID are arranged with respect to the input line and the signal line to form a SQUID arrangement such that the control currents that are coupled to the input line via the first SQUID and the second SQUID are in opposite directions, thereby cancelling the control currents induced in the input line. Similarly, the SQUID arrangement causes the control currents that are coupled to the signal line via the first SQUID and the second SQUID to be in opposite directions, thereby cancelling the control currents induced in the signal line.

In some examples, the balanced SQUID tunable coupler proposed herein eliminates complicated calibration procedures that is otherwise needed to cancel the control currents induced in the input line and the signal line. This in turn enables the reduction of the testing time, thereby reducing the cost. Furthermore, using two SQUIDS instead of one, allows for utilization of SQUIDS with smaller inductance to achieve the same coupling. SQUIDS with smaller inductance facilitates the use of JJs with smaller inductance in the SQUIDS. JJs with smaller inductance corresponds to SQUID junction that is larger (e.g., larger JJs). In some examples, using SQUIDS with larger JJs provides for better dynamic range (e.g., facilitates more input current to be coupled into the signal line).

In some examples, the coupling between the input line and the signal line can be positive and negative. In other words, signal line current that is induced in the signal line may be in phase with the input current (e.g., positively coupled) for a first period of time and may be out of phase, like 180⁰ out of phase (e.g., negatively coupled) for a second period of time. In some examples, the magnitude of the positively coupled signal line current may be smaller than the negatively coupled signal line current, or vice versa. In order to achieve an even positive/negative coupling magnitudes, the balanced SQUID tunable coupler proposed herein includes a coupling element that is inductively coupled to the input line and/or the signal line to add/provide a fixed positive coupling or a fixed negative coupling in the balanced SQUID tunable coupler. In some examples, the coupling element includes grounded loops that are inductively coupled to the input line and/or the signal line. The grounded loops add/provide a fixed positive coupling or a fixed negative coupling between the input line and the signal line, thereby balancing the positive/negative coupling magnitudes.

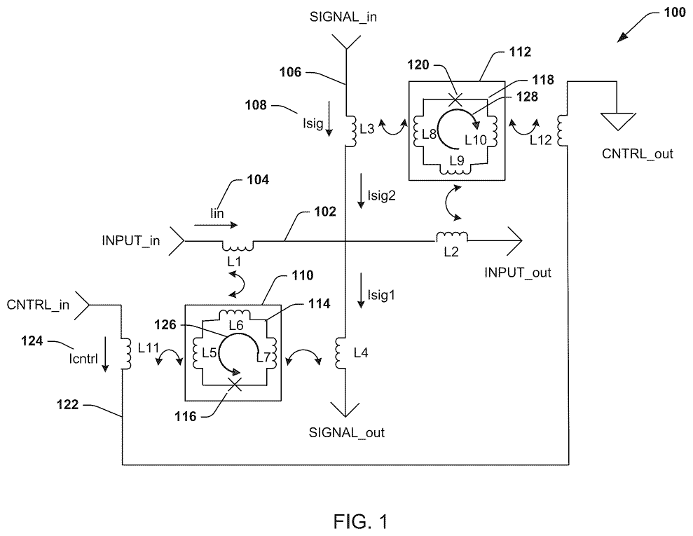

FIG. 1 illustrates an example of a tunable coupler system 100. The tunable coupler system 100 may be implemented as an integrated circuit (IC). The tunable coupler system 100 includes an input line 102 having an input port INPUT_in and an output port INPUT_out, that is configured to receive an input current Iin 104 (e.g., a DC signal) at the input port INPUT_in. The input line 102 has an input line inductance depicted by the inductances L1 and L2. The tunable coupler system 100 further includes a signal line 106 having an input port SIGNAL_in and an output port SIGNAL_out and configured to provide a signal line current Isig 108 (e.g., a DC signal) at the output port SIGNAL_out. The signal line 106 has a signal line inductance depicted by the inductances L3 and L4. The tunable coupler system 100 furthermore includes a first superconducting quantum interference device (SQUID) 110 and a second SQUID 112, both of which are inductively coupled to the input line 104 and the signal line 108.

Both the first SQUID 110 and the second SQUID 112 includes a radio frequency (RF) SQUID having a single Josephson Junction (JJ). However, other implementations of the first SQUID 110 and the second SQUID 112 are also contemplated to be within the scope of this disclosure. The first SQUID 110 includes a first superconducting loop 114 having a loop inductance depicted by the inductances L5, L6 and L7, and a first Josephson Junction (JJ) 116. Further, the second SQUID 112 includes a second superconducting loop 118 having a loop inductance depicted by the inductances L8, L9 and L10, and a second JJ 120. In some examples, the first SQUID 110 and the second SQUID 112 are identical to one another. In addition, the tunable coupler system 100 includes a control line 122 having an input port CNTRL_in and an output port CNTRL_out, and configured to receive a control current Icntrl 124 (e.g., a DC signal) at the input port CNTRL_in. The control line 122 is inductively coupled to the first SQUID 110 and the second SQUID 114. The control line 122 has a control line inductance depicted by the inductances L11 and L12.

The first SQUID 110 and the second SQUID 112 are configured to couple the input current Iin 104 in the input line 102 to the signal line 106 to form the signal line current Isig 108 based on the control current Icntrl 124 in the control line 122. In particular, the control current Icntrl 124 in the control line 122 determines a coupling strength between the input line 102 and the signal line 106. For example, the first SQUID 110 is configured to couple the input current Iin 104 in the input line 102 to the signal line 106 based on a mutual inductance M_{IN-SQUID1} between the input line 102 and the first SQUID 110 and a mutual inductance M_{SIG-SQUID1} between the signal line 106 and the first SQUID 110, as illustrated above in equation (1). Similarly, the second SQUID 112 is configured to couple the input current Iin 104 in the input line 102 to the signal line 106 based on a mutual inductance M_{IN-SQUID2} between the input line 102 and the second SQUID 112 and a mutual inductance M_{SIG-SQUID2} between the signal line 106 and the second SQUID 112, as illustrated above in equation (1). The control current Icntrl 124 in the control line 122 determines the mutual inductance M_{IN-SQUID1} between the input line 102 and the first SQUID 110, and the mutual inductance M_{SIG-SQUID1} between the signal line 106 and the first SQUID 110. Similarly, the control current Icntrl 124 in the control line 122 determines the mutual inductance M_{IN-SQUID2} between the input line 102 and the second SQUID 112, and the mutual inductance M_{SIG-SQUID2} between the signal line 106 and the second SQUID 112.

The first SQUID 110 and the second SQUID 112 are arranged with respect to the input line 102 and the signal line 106 to form a SQUID arrangement such that the input current Iin 104 in the input line 102 couples to the first SQUID 110 and the second SQUID 112 to induce a first signal line current Isig1 in the signal line 106 and a second signal line current Isig2 in the signal line 106, respectively. In some examples, the input current Iin 104 in the input line 102 induces a circulating current 126 in the first SQUID 110 based on the mutual inductance M_{IN-SQUID1}, which then couples to the signal line 106 based on the mutual inductance M_{SIG-SQUID1} to induce the first signal line current Isig1 in the signal line 106. Similarly, the input current Iin 104 in the input line 102 induces a circulating current 128 in the second SQUID 112 based on the mutual inductance M_{IN-SQUID2} which then couples to the signal line 106 based on the mutual inductance M_{SIG-SQUID2} to induce the second signal line current Isig2 in the signal line 106.

The first SQUID 110 and the second SQUID 112 are arranged with respect to the input line 102 and the signal line 106 to form the SQUID arrangement such that the first signal line current Isig1 and the second signal line current Isig2 are in the same direction (e.g., additive). In some examples, the first signal line current Isig1 and the second signal line current Isig2 are equal in magnitude. The signal line current Isig 108 is a summation of the first signal line current Isig1 and the second signal line current Isig2. In this example, the SQUID arrangement includes the input line 102 arranged perpendicular to the signal line 106, and the first SQUID 110 and the second SQUID 112 arranged diagonally with respect to one another in diagonally opposite quadrants formed by the input line 102 and the signal line 106. However, other arrangements of the input line 102, the signal line 106, the first SQUID 110 and the second SQUID 112 to form the SQUID arrangement are also contemplated to be within the scope of this disclosure.

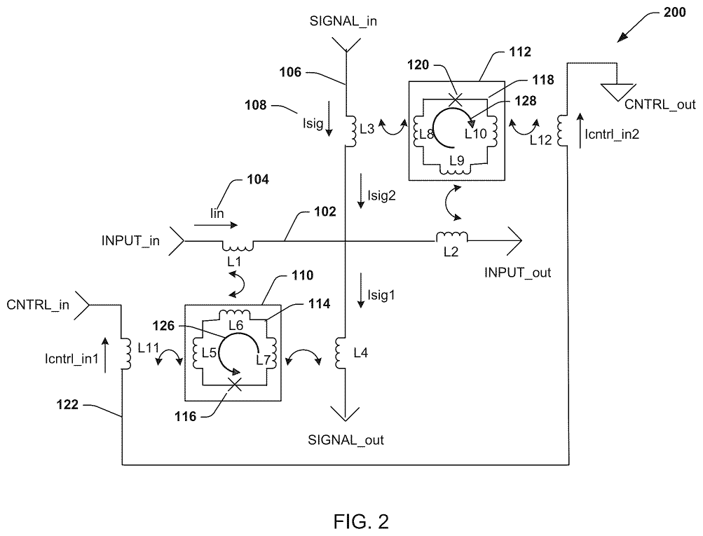

The input current Iin 104 coupled to the first SQUID 110 and the second SQUID 112 further induces a first control line input current Icntrl_in1 and a second control line input current Icntrl_in2, respectively, in the control line 122, as illustrated in FIG. 2. In particular, FIG. 2 illustrates an example tunable coupler system 200 having the first control line input current Icntrl_in1 and the second control line input current Icntrl_in2 in the control line 122. The tunable coupler system 200 in FIG. 2 is the same as the tunable coupler system 100 in FIG. 1 and therefore, the same numbering is utilized to depict the same structure. Although the tunable coupler system 200 includes the control current I cntrl 124, the control current I cntrl 124 is not depicted in FIG. 2 for clarity purposes. In some examples, the circulating current 126 induced by the input current Iin 104 in the first SQUID 110 couples to the control line 122 to induce the first control line input current Icntrl_in1 in the control line 122 and the circulating current 128 induced by the input current Iin 104 in the second SQUID 112 couples to the control line 122 to induce the second control line input current Icntrl_in2 in the control line 122. The first control line input current Icntrl_in1 and the second control line input current Icntrl_in2 are unwanted currents. Therefore, first SQUID 110 and the second SQUID 112 are arranged with respect to the input line 102 and the signal line 106 to form the SQUID arrangement such that the first control line input current Icntrl_in1 and the second control line input current Icntrl_in2 are in opposite directions, thereby cancelling each other.

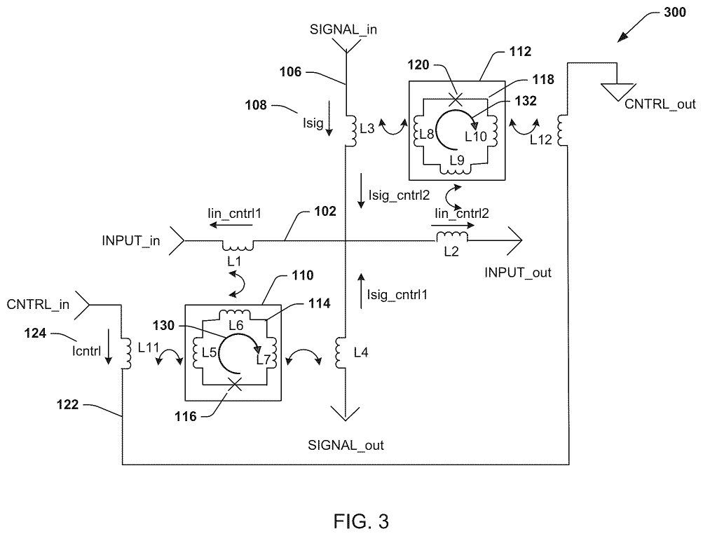

Referring back to FIG. 1, the SQUID arrangement further causes the control current Icntrl 124 in the control line 122 to couple to the first SQUID 110 and the second SQUID 112 to induce a first input line control current Iin_cntrl1 and a second input line control current Iin_cntrl2, respectively, in the input line 102, as illustrated in FIG. 3. In particular, FIG. 3 illustrates an example tunable coupler system 300 having first input line control current Iin_cntrl1 and the second input line control current Iin_cntrl2 in the input line 102. The tunable coupler system 300 in FIG. 3 is the same as the tunable coupler system 100 in FIG. 1 and therefore, the same numbering is utilized to depict the same structure. The control current Icntrl 124 in the control line 122 induces a circulating current 130 in the first SQUID 110 which couples to the input line 102 to induce the first input line control current Iin_cntrl1 in the input line 102. Further, the control current Icntrl 124 in the control line 122 induces a circulating current 132 in the second SQUID 112 which couples to the input line 102 to induce the second input line control current Iin_cntrl1 in the input line 102. The first input line control current Iin_cntrl1 and the second input line control current Iin_cntrl2 are unwanted currents. Therefore, first SQUID 110 and the second SQUID 112 are arranged with respect to the input line 102 and the signal line 106 to form the SQUID arrangement such that the first input line control current Iin_cntrl1 and the second input line control current Iin_cntrl2 are in opposite directions, thereby cancelling each other.

The control current Icntrl 124 coupled to the first SQUID 110 and the second SQUID 112 further induces a first signal line control current Isig_cntrl1 and a second signal line control current Isig_cntrl2, respectively, in the signal line 106 as illustrated in FIG. 3. In some examples, the circulating current 130 induced by the control current Icntrl 124 in the first SQUID 110 couples to the signal line 106 to induce the first signal line control current Isig_cntrl1 in the signal line 106 and the circulating current 132 induced by the control current Icntrl 124 in the second SQUID 112 couples to the signal line 106 to induce the second signal line control current Isig_cntrl2 in the signal line 106. The first signal line control current Isig_cntrl1 and the second signal line control current Isig_cntrl2 are unwanted currents. Therefore, first SQUID 110 and the second SQUID 112 are arranged with respect to the input line 102 and the signal line 106 to form the SQUID arrangement such that the first signal line control current Isig_cntrl1 and the second signal line control current Isig_cntrl2 are in opposite directions, thereby cancelling each other.

Referring back to FIG. 1, the input current Iin 104 may be positively coupled to the signal line 106 or negatively coupled to the signal line 106. During positive coupling, the signal line current 108 that is induced in the signal line 106 is in phase with the input current Iin 104 and during negative coupling, the signal line current Isig 108 that is induced in the signal line 106 is out of phase, like 180⁰ out of phase with the input current Iin 104. In some examples, the input current Iin 104 may be positively coupled to the signal line 106 for a first period of time and negatively coupled to the signal line 106 for a second period of time. A value of the control current Icntrl 124 in the control line 122 determines whether the input current Iin 104 is positively coupled to the signal line 106 or negatively coupled to the signal line 106. In some examples, a magnitude of the positively coupled portion of the signal line current 108 may be lesser than a magnitude of the negatively coupled portion of the signal line current 108. In order to make the magnitudes of the positively coupled portion and the negatively coupled portion of the signal line current 108 substantially equal, in some examples, the tunable coupler system 100 further includes a coupling element (not shown here) that are inductively coupled to the input line 102 and/or the signal line 106 to add/provide a fixed positive coupling or a fixed negative coupling between the input line 102 and the signal line 106. In some examples, the coupling element is implemented using grounded loops that are inductively coupled to the input line 102 and/or the signal line 106, as can be fully appreciated in the examples below. However, in other examples, the coupling element may be implemented differently. In some examples, the tunable coupler system 100 may further include fixed DC biasing (not shown here). In some examples, providing the fixed DC biasing facilitates to set an initial value of the control current Icntrl 124 at a certain value above 0.

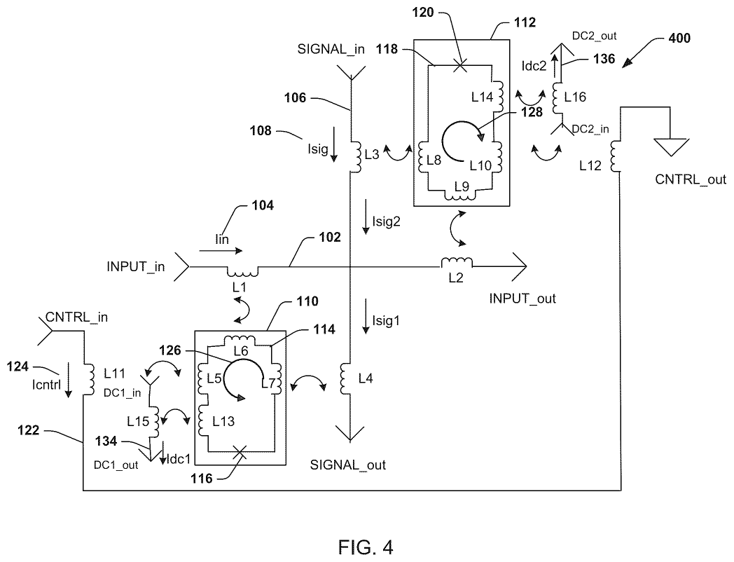

FIG. 4 illustrates an example implementation of a tunable coupler system 400 that includes fixed DC biasing. The tunable coupler system 400 has features similar to that of the tunable coupler system 100 in FIG. 1 and therefore, same numbering is used to depict the same structure. Further, the tunable coupler system 400 functions in a manner similar to the tunable coupler system 100 in FIG. 1 and therefore, all the explanations related to the tunable coupler system 100 are also applicable herein. In the tunable coupler system 400, the loop inductance of the first conducting loop 116 is depicted by the inductances L5, L6, L7 and L13, and the loop inductance of the second conducting loop 118 is depicted by the inductances L8, L9, L10 and L14. The tunable coupler system 400 further includes a first DC bias line 134 having a DC line inductance L15 and configured to receive a first DC current Idc1. Further, the tunable coupler system 400 includes a second DC bias line 136 having a DC line inductance L16 and configured to receive a second DC current Idc2. The first DC bias line 134 is inductively coupled to the first SQUID 110 and configured to provide a first constant DC bias to the first SQUID 110, based on the first DC current Idc1. Further, the second DC bias line 136 is inductively coupled to the second SQUID 112 and configured to provide a second constant DC bias to the second SQUID 112, based on the second DC current Idc2. In some examples, providing the first constant DC bias and the second constant DC bias facilitates to set an initial value of the control current Icntrl 124 at a certain value above 0.

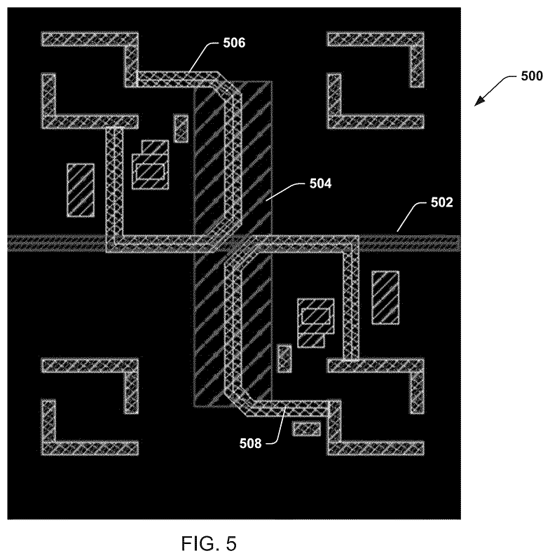

FIG. 5 illustrates an example layout of an integrated circuit (IC) that includes a tunable coupler system 500 showing grounded loops. In some examples, the tunable coupler system 500 is similar to the tunable coupler system 100 in FIG. 1. The various elements of the tunable coupler system 500 may be implemented in different layers associated with the IC with dielectric layers disposed therebetween. The tunable coupler system 500 includes an input line 502 and a signal line 504. The input line 502 is implemented in a first layer associated with the IC and the signal line 504 is implemented in a second layer associated with the IC. Although not shown here, the tunable coupler system 500 includes a first SQUID and a second SQUID. In some examples, the first SQUID and the second SQUID are implemented in a third layer associated with the IC. Further, the tunable coupler system 500 includes a control line (not shown) implemented in a fourth layer associated with the IC. In addition, the tunable coupler system 500 includes a first grounded loop 506 and a second grounded loop 508 that forms a first pair of ground loops. The first pair of grounded loops is implemented in a fifth layer of the IC. The first grounded loop 506 includes a conducting loop that is coupled to a circuit ground. Similarly, the second grounded loop 508 includes a conducting loop that is coupled to the circuit ground.

In some examples, the tunable coupler system 500 further includes a third grounded loop (not shown) that is arranged below the first grounded loop 506 and a fourth grounded loop (not shown) that is arranged below the second grounded loop 508. The third grounded loop and the fourth grounded loop form a second pair of grounded loops and the second pair of grounded loops is arranged in a sixth layer of the IC. The third grounded loop includes a conducting loop that is coupled to the circuit ground and the fourth grounded loop includes a conducting loop that is coupled to the circuit ground. In some examples, the fifth layer (e.g., where the first pair of grounded loops is arranged) is above the third layer (e.g., where the first SQUID and the second SQUID are arranged) and the sixth layer (e.g., where the second pair of grounded loops is arranged) is below the third layer. In some examples, the first grounded loop 506 is arranged to overlap (e.g., extend at least partly over) the first SQUID and the third grounded loop is arranged to underlap (e.g., extend at least partly under) the first SQUID. Further, the second grounded loop 508 is arranged to overlap (e.g., extend at least partly over) the second SQUID and the fourth grounded loop is arranged to underlap (e.g., extend at least partly under) the second SQUID.

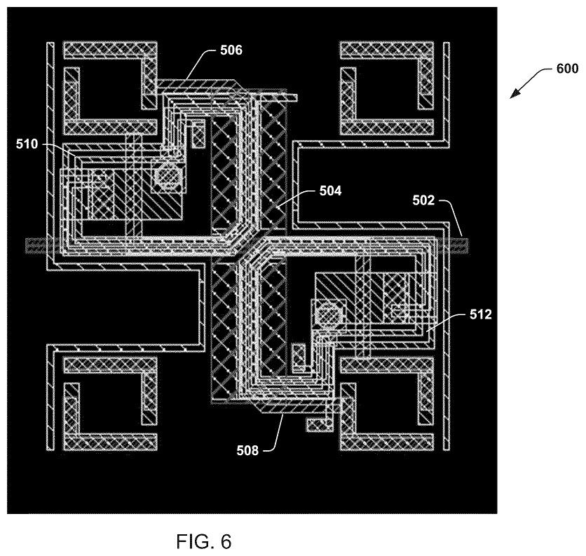

FIG. 6 illustrates an example layout of an integrated circuit (IC) that includes a tunable coupler system 600 showing a SQUID arrangement. The tunable coupler system 600 is same as the tunable coupler system 500 in FIG. 5 and therefore, the same numbering is used herein to depict the same structure. The tunable coupler system 600 shows a first SQUID 510 and a second SQUID 512. The first SQUID 510 and the second SQUID 512 are same as the first SQUID and the second SQUID, respectively, of the tunable coupler system 500 in FIG. 5. All the features of the tunable coupler system 500 are also applicable to the tunable coupler system 600, and therefore the explanations are not repeated herein.

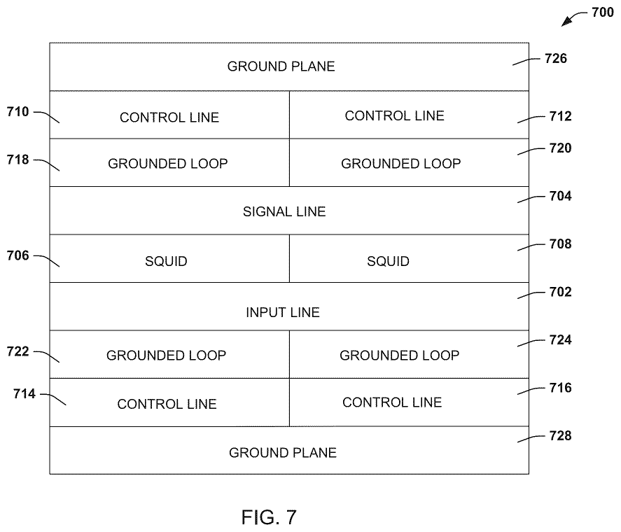

FIG. 7 illustrates an example cross-section of an integrated circuit (IC) 700 that includes a tunable coupler system. The tunable coupler system in the IC 700 is similar to the tunable coupler system 100 in FIG. 1 and therefore, all the features of the tunable coupler system 100 is also applicable herein. The IC 700 includes an input line 702 implemented in a first layer of the IC 700 and a signal line 704 implemented in a second layer of the IC 700. In this example, the input line 702 is implemented in a layer below the signal line 704. However, in other examples, the input line 702 may be implemented in a layer above the signal line 704. The IC 700 further includes a first SQUID 706 and a second SQUID 708 implemented in a third layer of the IC 700. The third layer is between the first layer and the second layer. Furthermore, the IC 700 includes a control line. The control line may be implemented as two separate control lines 710 and 712 in a fourth layer associated with the IC 700. The control lines 710 and 712 are coupled to one another. Alternately, the control line may be implemented as two separate control lines 714 and 716 in a fifth layer of the IC 700. The control lines 714 and 716 are coupled to one another.

The IC 700 further includes a first grounded loop 718 and a second grounded loop 720, both of which are arranged in a fifth layer of the IC 700. The first grounded loop 718 and the second grounded loop 720 forms a first pair of grounded loops. Additionally, or alternately, the IC 700 includes a third grounded loop 722 and a fourth grounded loop 724, both of which are arranged in a sixth layer of the IC 700. The third ground loop 722 and the fourth grounded loop 724 forms a second pair of grounded loops. In addition, the IC 700 includes a ground plane 726 and a ground plane 728 arranged in a seventh layer and eighth layer, respectively, of the IC 700. It is noted that the terms first, second, third etc. are used herein not to show a temporal or spatial relationship, but just for distinction purposes (e.g., to show distinct layers). It is also noted that dielectric layers are disposed between conductive elements to assure proper galvanic isolation between conductive elements.

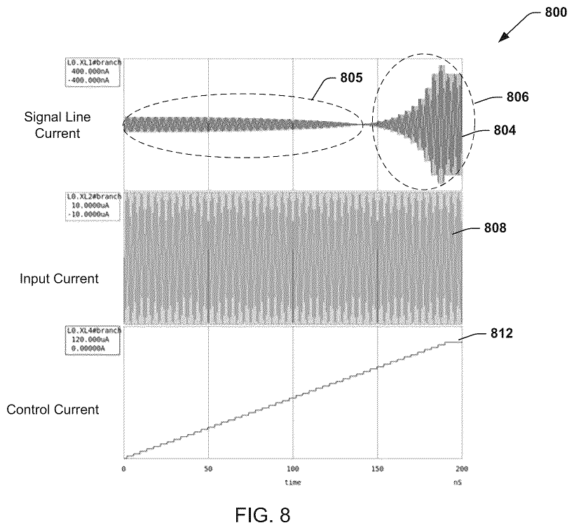

FIG. 8 illustrates a graphical representation 800 of a signal line current 804, an input current 808 and a control current 812 associated with a tunable coupler system without including a coupling element (e.g., grounded loops). In some examples, the signal line current 804, the input current 808 and the control current 812 may correspond to the signal line current Isig 108, the input current Iin 104 and the control current Icntrl 124, respectively, of the tunable coupler system 100 of FIG. 1. The signal line current Isig 804 includes a positively coupled portion 805 and a negatively coupled portion 806. As can be seen in FIG. 8, without adding the coupling element (e.g., the ground loops), a magnitude of the positively coupled portion 805 is less than a magnitude of the negatively coupled portion 806.

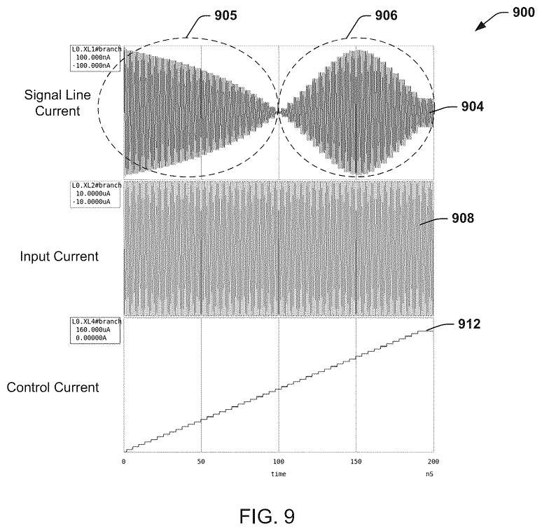

FIG. 9 illustrates a graphical representation 900 of a signal line current 904, an input current 908 and a control current 912 associated with a tunable coupler system that includes a coupling element (e.g., grounded loops). In some examples, the signal line current 804, the input current 808 and the control current 812 may correspond to the signal line current Isig 108, the input current Iin 104 and the control current Icntrl 124, respectively, of the tunable coupler system 100 of FIG. 1. The signal line current Isig 904 includes a positively coupled portion 905 and a negatively coupled portion 906. As can be seen in FIG. 9, by adding the coupling element (e.g., the ground loops), a magnitude of the positively coupled portion 905 becomes approximately equal to a magnitude of the negatively coupled portion 906.

What have been described above are examples of the disclosure. It is, of course, not possible to describe every conceivable combination of components or method for purposes of describing the disclosure, but one of ordinary skill in the art will recognize that many further combinations and permutations of the disclosure are possible. Accordingly, the disclosure is intended to embrace all such alterations, modifications, and variations that fall within the scope of this application, including the appended claims.

What is claimed is:

1. A tunable coupler system comprising:
an input line configured to receive an input current;
a signal line configured to provide a signal line current;
a first superconducting quantum interference device (SQUID) inductively coupled to the input line and the signal line;
a second SQUID inductively coupled to the input line and the signal line; and
a control line inductively coupled to the first SQUID and the second SQUID,
wherein the first SQUID and the second SQUID are configured to couple the input current in the input line to the signal line to form the signal line current, wherein a coupling strength between the input line and the signal line is determined based on a control current in the control line.

2. The tunable coupler system of claim 1, wherein the first SQUID and the second SQUID are arranged with respect to the input line and the signal line to form a SQUID arrangement such that the input current in the input line couples to the first SQUID and the second SQUID to induce a first signal line current in the signal line and a second signal line current in the signal line, respectively, wherein the first signal line current and the second signal line current are in the same direction.

3. The tunable coupler system of claim 2, wherein the signal line current is a summation of the first signal line current and the second signal line current.

4. The tunable coupler system of claim 2, wherein the input current coupled to the first SQUID and the second SQUID further induces a first control line input current in the control line and a second control line input current in the control line, respectively, wherein the first control line input current and the second control line input current are in opposite directions.

5. The tunable coupler system of claim 4, wherein the first control line input current and the second control line input current cancel each other.

6. The tunable coupler system of claim 2, wherein the SQUID arrangement causes the control current in the control line to couple to the first SQUID and the second SQUID to induce a first input line control current in the input line and a second input line control current in the input line, respectively, wherein the first input line control current and the second input line control current are in opposite directions.

7. The tunable coupler system of claim 6, wherein the first input line control current and the second input line control current cancel one another.

8. The tunable coupler system of claim 2, wherein the control current coupled to the first SQUID and the second SQUID further induces a first signal line control current in the signal line and a second signal line control current in the signal line, respectively, wherein the first signal line control current and the second signal line control current are in opposite directions.

9. The tunable coupler system of claim 8, wherein the first signal line control current and the second signal line control current cancel one another.

10. The tunable coupler system of claim 1, further comprising a coupling element that is inductively coupled to the input line and/or the signal line and configured to provide a fixed positive coupling or a fixed negative coupling between the input line and the signal line.

11. The tunable coupler system of claim 10, wherein the coupling element includes grounded loops that are inductively coupled to the input line and/or the signal line.

12. The tunable coupler system of claim 11, wherein the tunable coupler system is implemented as part of an integrated circuit (IC), wherein the first SQUID and the second SQUID are included in a first layer associated with the IC and wherein the grounded loops comprise a first pair of grounded loops included in a second layer above the first layer or a second pair of grounded loops included in a third layer below the first layer, or both.

13. The tunable coupler system of claim 1, wherein a value of the control current in the control line determines whether the input current is positively coupled to the signal line or negatively coupled to the signal line.

14. The tunable coupler system of claim 1, further comprising:
a first DC bias line inductively coupled to the first SQUID and configured to provide a first constant DC bias to the first SQUID; and
a second DC bias line inductively coupled to the second SQUID and configured to provide a second constant DC bias to the second SQUID.

15. The tunable coupler system of claim 1, wherein the first SQUID and the second SQUID each comprise a radio frequency (RF) SQUID having a single Josephson Junction (JJ).

16. An integrated circuit (IC) comprising:
an input line included in a first layer of the IC;
a signal line included in a second layer of the IC;
a first superconducting quantum interference device (SQUID) and a second SQUID included in a third layer of the IC such that the first SQUID and the second SQUID are inductively coupled to the input line and the signal line; and
a control line included in a fourth layer of the IC such that the control line is inductively coupled to the first SQUID and the second SQUID;
wherein the first SQUID and the second SQUID are configured to couple an input current in the input line to the signal line, wherein a coupling strength between the input line and the signal line is determined based on a control current in the control line.

17. The IC of claim 16, wherein the first SQUID and the second SQUID are arranged with respect to the input line and the signal line to form a SQUID arrangement such that the input current in the input line couples to the first SQUID and the second SQUID to induce a first signal line current in the signal line and a second signal line current in the signal line, respectively, wherein the first signal line current and the second signal line current are in the same direction.

18. The IC of claim 17, wherein the SQUID arrangement causes the control current in the control line to couple to the first SQUID and the second SQUID to induce a first input line control current in the input line and a second input line control current in the input line, respectively, wherein the first input line control current and the second input line control current are in opposite directions.

19. The IC of claim 18, wherein the control current coupled to the first SQUID and the second SQUID further induces a first signal line control current in the signal line and a second signal line control current in the signal line, respectively, wherein the first signal line control current and the second signal line control current are in opposite directions.

20. The IC of claim 16, further comprising a first pair of grounded loops included in a fifth layer of the IC or a second pair of grounded loops included in a sixth layer of the IC, or both, wherein the fifth layer is above the third layer and the sixth layer is below the third layer.
